(19) United States
(12) Patent Application Publication
(10) Pub. No.: US 2017/0077196 A1
(43) Pub. Date: Mar. 16, 2017

(54) DISPLAY DEVICE

(71) Applicant: Japan Display Inc., Tokyo (JP)

(72) Inventor: Noriyoshi KANDA, Tokyo (JP)

(21) Appl. No.: 15/258,121

(22) Filed: Sep. 7, 2016

(30) Foreign Application Priority Data
Sep. 15, 2015 (JP) 2015-181713

(51) Int. Cl. H01L 27/32; H01L 51/56; H01L 51/52

(52) U.S. Cl. CPC H01L 27/3246; H01L 51/5253; H01L 51/5215; H01L 51/56; H01L 27/322; H01L 27/3272; H01L 2227/323

(57) ABSTRACT

A display device includes a display region arranged with a plurality of pixels in a matrix shape, a pixel electrode including at least a first conductive layer and a second conductive layer, an end part of the second conductive layer existing further to the exterior than an end part of the first conductive layer, a protective layer covering a region spreading further to the exterior than an end part of the first conductive layer of the second conductive layer so as to expose a part of a surface of the second conductive layer of a region stacked with the first conductive layer and the second conductive layer, and a bank layer covering an end part of the pixel electrode and an end part of the protective layer so as to expose a part of the second conductive layer.

### CROSS-REFERENCE TO RELATED APPLICATIONS

This application is based upon and claims the benefit of priority from the prior Japanese Patent Application No. 2015-181713, filed on Sep. 15, 2015, the entire contents of which are incorporated herein by reference.

### FIELD

The present invention is related to a display device.

### BACKGROUND

A display device such as a thin type display is arranged with an electrode (pixel electrode) in each pixel. For example, in a display device which uses a current drive type element such as an OLED (Organic Light Emitting Diode), an OLED current is supplied to each pixel electrode (for example, Japanese Laid Open Patent Publication No. 2007-220393).

In the case of such a display device, content to be displayed is determined by the current supplied to each pixel electrode. As a result, due to various circumstances involved in the manufacturing process, when adjacent pixel electrodes become electrically connected (short), current control to mutually connected pixel electrodes is no longer possible leading to display defects.

### SUMMARY

One embodiment of the present invention provides a display device including a display region arranged with a plurality of pixels in a matrix shape, a pixel electrode arranged corresponding to the pixel, and including at least a first conductive layer and a second conductive layer arranged above the first conductive layer, an end part of the second conductive layer existing further to the exterior than an end part of the first conductive layer, a protective layer arranged above the second conductive layer, and covering a region spreading further to the exterior than an end part of the first conductive layer of the second conductive layer so as to expose a part of a surface of the second conductive layer of a region stacked with the first conductive layer and the second conductive layer, and a bank layer being an insulation material, and covering an end part of the pixel electrode and an end part of the protective layer so as to expose a part of the second conductive layer.

### BRIEF DESCRIPTION OF DRAWINGS

FIG. 1 is a diagram showing an approximate structural diagram of a display device in a first embodiment of the present invention;

FIG. 2 is a schematic diagram showing a cross-sectional structure in a display region of the display device in the first embodiment of the present invention;

FIG. 3 is a schematic diagram showing a positional relationship between a pixel electrode and a protective layer in the first embodiment of the present invention;

FIG. 4 is a diagram for explaining the processes for forming a thin film transistor in a manufacturing method of the display device in the first embodiment of the present invention;

FIG. 5 is a diagram for explaining a process after FIG. 4 of a manufacturing method of the display device in the first embodiment of the present invention;

FIG. 6 is a diagram for explaining a process after FIG. 5 of a manufacturing method of the display device in the first embodiment of the present invention;

FIG. 7A˜7E are diagrams showing an expanded view of an end part of a pixel electrode for explaining a process after FIG. 6 of a manufacturing method of the display device in the first embodiment of the present invention;

FIG. 8 is a diagram for explaining a process after FIG. 7A˜7E of a manufacturing method of the display device in the first embodiment of the present invention;

FIG. 9A˜9D are diagrams showing an expanded view of an end part of a pixel electrode for explaining a process after FIG. 8 of a manufacturing method of the display device in the first embodiment of the present invention;

FIG. 10 is a diagram for explaining the entire structure shown in FIG. 9C,

FIG. 11A˜11D are diagrams for explaining the processes corresponding to FIG. 9A˜9D in a manufacturing method of a display device in a second embodiment of the present invention;

FIG. 12A˜12C are diagrams for explaining an example of the problems that occur in a manufacturing method of a conventional display device; and

FIG. 13 is a diagram for explaining an example of the problems that occur in a manufacturing method of a conventional display device.

### DESCRIPTION OF EMBODIMENTS

Each embodiment of the present invention is explained below while referring to the diagrams. Furthermore, the disclosure is merely an example and appropriate modifications could be conceived while maintaining the scope of the invention which are also included in the scope of the present invention. In addition, in order to better clarify the invention, the width and shape etc of each part in the drawings are sometimes shown schematically compared to the actual forms and should not be interpreted as limiting the present invention. In addition, in the specification and each drawing, the same reference symbols are attached to similar elements which have previously been described and a detailed explanation of these elements may be omitted where appropriate.

### First Embodiment

### [Approximate Structure]

A display device in one embodiment of the present invention is an organic EL (electro-luminescence) display device using an OLED. The organic EL display device in this example uses an OLED which emits white light. The white light emitted from this OLED is passed through a color filter to obtain a color display.

The display device has a structure in which a first substrate and second substrate are bonded together. Drive elements such as a thin film transistor (TFT) for controlling the light emitting state of an OLED are arranged in the first substrate. Color filters and the like are formed in the second substrate. A filler may be arranged between the first substrate and second substrate so as to fill in any gaps.

A top emission type is used in which light from an OLED arranged in the first substrate is emitted to the opposite side of the first substrate, passes through a color filter arranged in the second substrate and is viewed by a user.

Furthermore, although a top emission type organic EL display device is used as an example of an embodiment in the present example, any display device is sufficient as long as it uses a pixel electrode having a certain stacked layer structure (described in detail below). For example, a bottom emission type organic EL display device or a display device using liquid crystals is also possible.

An aim in one embodiment of the present invention is to reduce defects caused by short circuits between pixel electrodes.

In the display device in one embodiment of the present invention, it is possible to suppress display defects occurring in a pixel electrode having a certain stacked layer structure as explained below.

### [External Structure of a Display Device 1000]

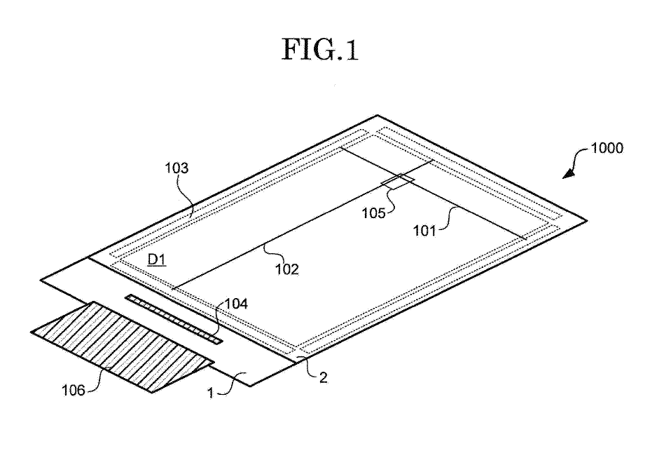

FIG. 1 is a diagram showing an approximate structure of a display device in one embodiment of the present invention. The display device 1000 is arranged with a first substrate 1 arranged with a display region D1 and scanning line drive circuit 103, and a second substrate 2 arranged to cover the display region D1 and scanning line drive circuit 103. In addition, the display device 1000 is arranged with a driver IC 104 attached to the first substrate 1 and a FPC (flexible printed circuit) 106. A color filter and the like is arranged in the second substrate 2.

A scanning line 101 and a data signal line 102 which intersects perpendicularly with the scanning line 101 are arranged in the display region D1. A pixel 105 is arranged at a position corresponding to an intersection part between the scanning line 101 and data signal line 102. The pixel 105 is arranged in a matrix shape. Furthermore, although one signal line extends in a direction along the scanning line 101 or data signal line 102 for each pixel 105 in FIG. 1, a plurality of signal lines is also possible. In addition, wiring for supplying a certain voltage such as a power source line may also be arranged in the display region D1.

The scanning line drive circuit 103 supplies a control signal to the scanning line 101. The driver IC 104 supplies a data voltage to the data signal line 102 and controls the scanning line drive circuit 103. Furthermore, other drive circuits may be further arranged in the periphery of the display region D1.

A display element including a pixel circuit for controlling emitted light based on a control signal and data voltage, and a light emitting element (OLED) in which emitted light is controlled by the pixel circuit are arranged in each pixel 105. A pixel circuit includes a thin film transistor and a condenser for example, drives the thin film transistor using a control signal and data voltage and controls the light emitted by a light emitting element. An image is displayed in the display region D1 by control of this emitted light.

### [Cross-Sectional Structure of Display Device 1000]

Next, a cross-sectional structure of the display device 1000 is explained. A cross-sectional structure of a pixel circuit and the like in the display region D1 is explained below.

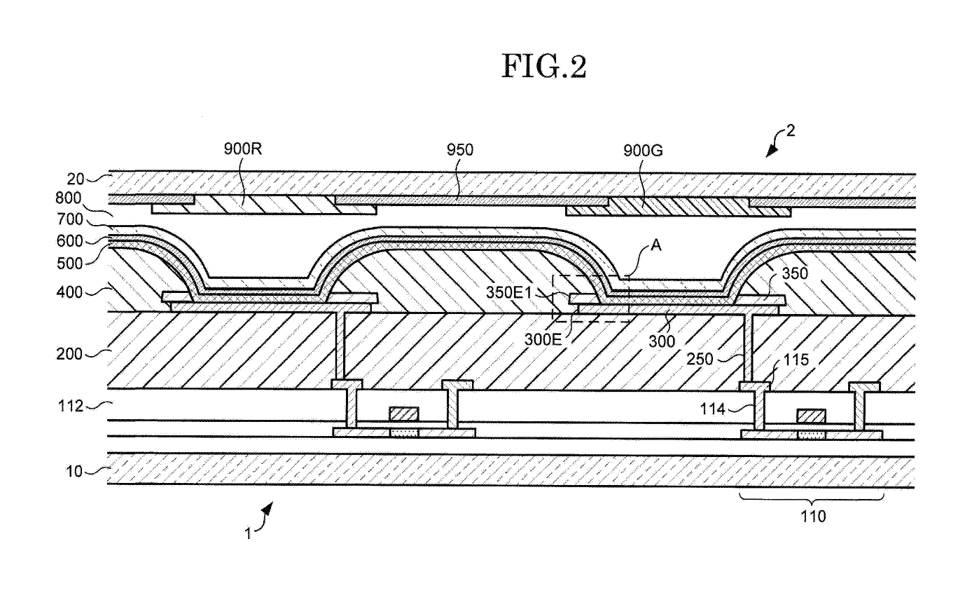

FIG. 2 is a schematic diagram showing a cross-sectional structure in a display region of a display device in the first embodiment of the present invention. In each case the cross-sectional structure explained below is represented as an end view. A first support substrate 10 in the first substrate 1 and a second support substrate 20 in the second substrate 2 are glass substrates. Furthermore, either one or both of the first support substrate 10 and the second support substrate 20 may be resin substrates having flexibility.

The structure of the first substrate 1 is explained. A thin film transistor 110 is arranged above the first support substrate 10. An interlayer insulation layer 200 is arranged so as to cover the thin film transistor 110. A pixel electrode 300 is arranged above the interlayer insulation layer 200. The interlayer insulation layer 200 is coated with a photosensitive acrylic resin for example, and is formed with a desired pattern by performing exposure, development and sintering. Since the interlayer insulation 200 also includes the role of planarizing a surface before a pixel electrode 300 is formed, an acrylic resin is favorable although an inorganic material also be used. Furthermore, although the interlayer insulation layer 200 is shown as a single layer in FIG. 2, a stacked layer of a plurality of insulation films is also possible. In this case, wiring may be arranged between the plurality of insulation films. In the present example, the interlayer insulation layer 200 has a stacked layer structure including not only an acrylic resin but also a silicon nitride film (SiN) on the other surface side, that is, on the surface side which contacts the pixel electrode 300.

The pixel electrode 300 is connected to a conductive layer 115 of the thin film transistor 110 via a contact hole 250 arranged in the interlayer insulation layer 200. The pixel electrode 300 is used as an OLED anode electrode. Here, since the display device 1000 displays an image using a top emission type method, the pixel electrode 300 does not have to include translucency. Therefore, the pixel electrode 300 may also include a layer which reflects light emitted by the OLED. In the present example, the pixel electrode 300 has a stacked layer structure in which a reflective layer (silver: Ag in the present example) having light reflecting properties, and a conductive layer (ITO: Indium Tin Oxide in the present example) including a metal oxide such as indium oxide having translucency so as to sandwich the reflective layer are stacked. A material having a high reflectance in the visible light range such as Ag or Al and the like is preferred for the reflecting layer.

While a metal oxide conductive layer is used on the OLED side since it has an advantageous work function due to its relationship with an OLED, it should not block light being reflected. Furthermore, by controlling film thickness to a certain value, it is possible to effectively emit light from the OLED to the exterior using a good interference effect. A thin layer compared to other films is required in order to obtain this effect. On the other hand, a metal oxide conductive layer on the side of the interlayer insulation layer 200 is used for its good adhesion with the interlayer insulation layer 200, good connectivity with a conductive layer of the thin film transistor 110 and relationship with the manufacturing process. A metal oxide conductive layer stacked on a reflective layer is preferred to be a film having these characteristics. Furthermore, a metal oxide conductive layer does not need to be present on the interlayer insulation layer 200 side.

A protective layer 350 is arranged at an exterior periphery end part of the pixel electrode 300 so as to cover the exterior periphery end part. The protective layer 350 is formed from an inorganic insulation material (silicon oxide: SiO2, silicon nitride: SiN and the like) or an inorganic conductive material (titanium: Ti, tantalum: Ta and the like). In the present example, the protective layer 350 is formed using a silicon oxide inorganic insulation material.

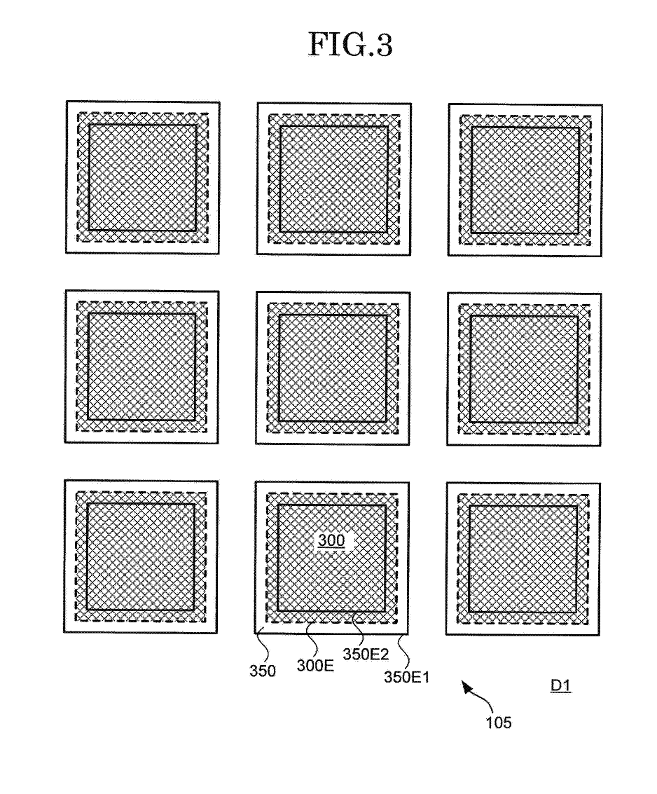

FIG. 3 is a schematic diagram showing the positional relationship between a pixel electrode and a protective layer in the first embodiment of the present invention. The pixel electrode 300 is the hatched part in FIG. 3. The dotted line section is an end part 300E of the pixel electrode 300. The protective layer 350 covers the end part 300E and is arranged in a ring shape so as to expose a part of the pixel electrode 300. That is, an exterior side end part 350E1 of the protective layer 350 is located at the same position as or further to the exterior than the end part 300E of the pixel electrode 300. An interior side end part 350E2 of the protective layer 350 is located on the interior side of the end part 300E of the pixel electrode 300. The interior side of the protective layer 350 corresponds to the side where the pixel electrode 300 is exposed. Details of the cross-sectional structure of the pixel electrode 300 and protective layer 350 are described below

Again referring to FIG. 2, a bank layer 400 covers the end part 300E of the pixel electrode 300 and the space between adjacent pixels and is arranged with an aperture part which exposes a part of the pixel electrode 300. In addition, in the present example, the bank layer 400 exposes a side wall of the interior side end part 350E2 of the protective layer 350 and covers the exterior side end part 350E1. The bank layer 400 may cover all of the upper surface of the protective layer 350 or may expose a part of the interior side end part 350E2 side of the upper surface. In the case where the bank layer 400 covers all of the upper surface of the protective layer 350, the surface of the bank layer 400 and the side wall of the interior side end part 350E2 of the protective layer 350 are said to be consecutively linked. In this consecutively linked state, the inclination of the surface of the bank layer 400 and the inclination of the side wall of the interior side end part 350E2 may be the same or different respectively. The bank layer 400 is formed from an organic insulation material such as an acrylic resin.

A light emitting layer 500 is an OLED which covers the pixel electrode 300 and bank layer 400 and contacts with this structure. At this time, the light emitting layer 500 also contacts with the side wall of the interior side end part 350E2 of the protective layer 350. A translucent electrode 600 covers the light emitting layer 500 and forms a cathode (opposing electrode with respect to the pixel electrode 300) of the OLED. The translucent electrode 600 is an electrode which allows light from the OLED to pass through and is formed from a metal oxide such as ITO or IZO for example or a thin metal layer sufficient to allow light to pass through. A sealing layer 700 is a layer for suppressing components which degrade a light emitting layer such as water or gas and the like from reaching the light emitting layer 500 and is an inorganic insulation layer such as silicon nitride covering the translucent electrode 600.

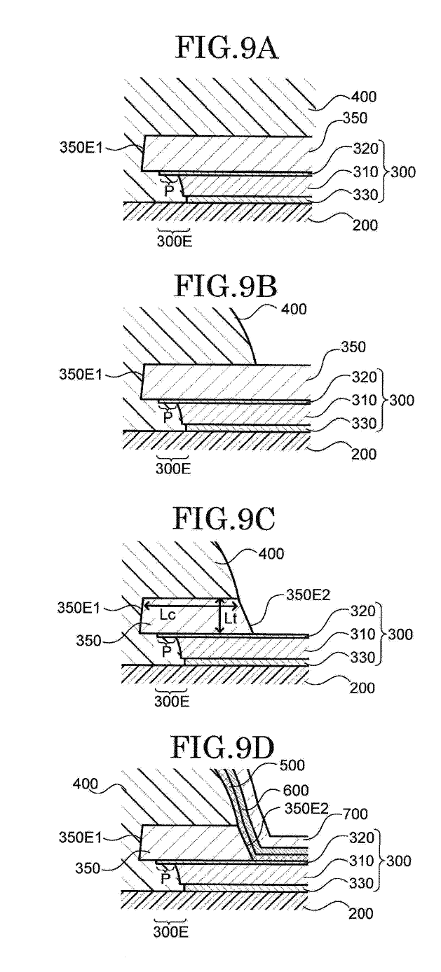

Light which displays an image is emitted by passing through the translucent electrode 600 when a current is supplied to the light emitting layer 500 via the pixel electrode 300 and translucent electrode 600. As a result, a region of the pixel electrode 300 exposed by the bank layer 400 and the protective layer 350 serves as a light emitting region. The expanded image of the region A in FIG. 2 corresponds to the image shown in FIG. 9D described below. This completes the explanation of the first substrate 1.

Next, the structure of the second substrate 2 is explained. A light shielding layer 950 and color filters 900R, 900G, 900B and 900W corresponding to red (R), green (G), blue (B) and white (W) are arranged in a second support substrate 20. The color filters 900B and 900W are omitted from FIG. 2. The light shielding layer 950 is formed from a material having light shielding properties such as metal. In addition, the light shielding layer 950 is arranged in a boundary part of different color pixels and a region on the exterior side of the display region D1.

The color filters 900R, 900G, 900B and 900W are arranged corresponding to a light emitting region in each pixel. The color filters 900R, 900G, 900B and 900W are coated with a photosensitive resin including a pigment representing each color and become layers formed with a desired pattern via exposure, development and sintering processes. The color filter 900W may also be formed by a resin which does not include a pigment. A printing method or an inkjet method may be used to form the color filters.

A filler material 800 is filled between the first substrate 1 and second substrate 2 and is comprised from acrylic resin for example. Translucency is necessary in the case where the filler material 800 is arranged in the display region D1. In addition, the filler material 800 may also be used as a material for bonding together and fixing the first substrate 1 and second substrate 2.

### [Manufacturing Method of Display Device 1000]

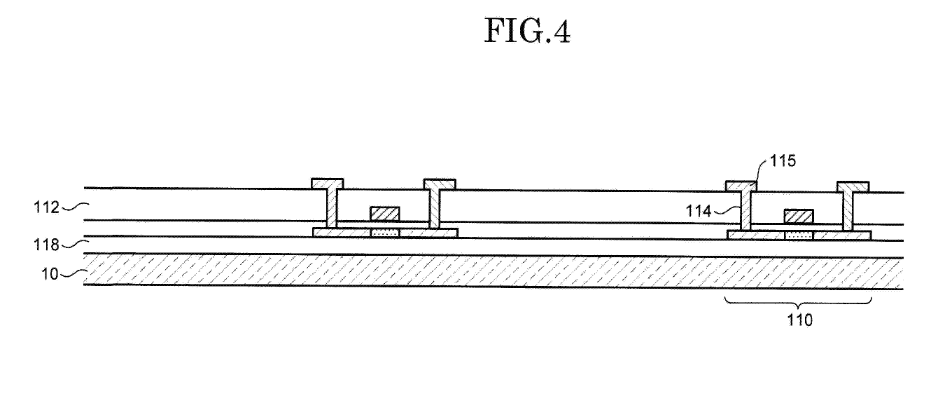

Next, a manufacturing method of the display device 1000 described above is explained using FIG. 4 to FIG. 10.

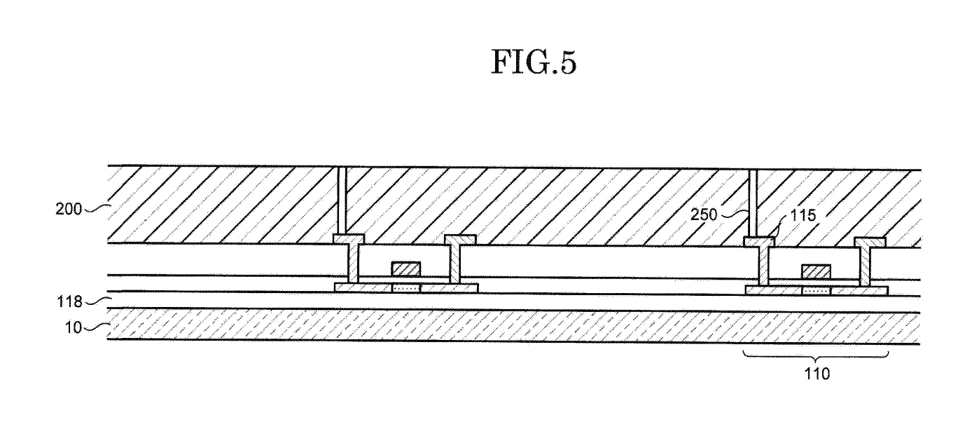

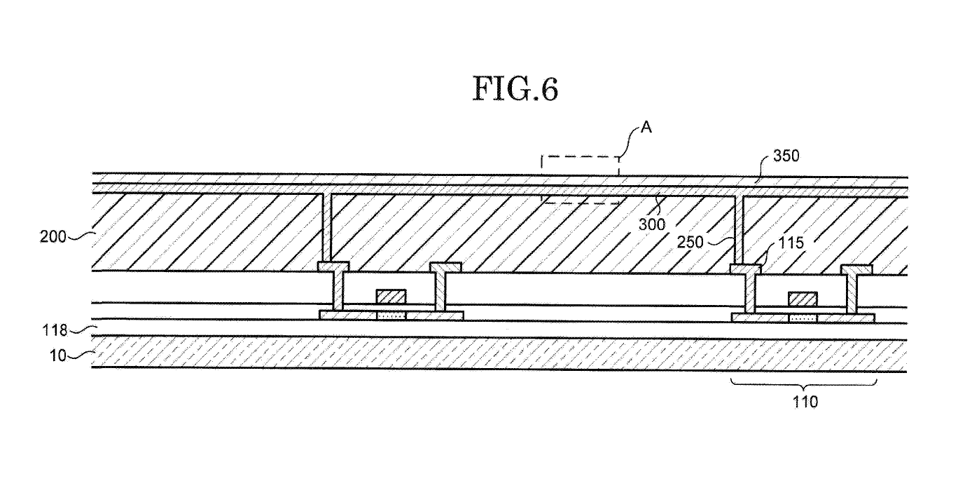

FIG. 4 is a diagram for explaining a process for forming a thin film transistor in the manufacturing method of the display device in the first embodiment of the present invention. FIG. 5 is a diagram for explaining a process after FIG. 4 in the manufacturing method of the display device in the first embodiment of the present invention. FIG. 6 is a diagram for explaining a process after FIG. 5 in the manufacturing method of the display device in the first embodiment of the present invention. First, the thin film transistor 110 is formed in the first support substrate 10 (FIG. 4). Here, the thin film transistor 110 is arranged with a source, drain, interlayer insulation layer 112 arranged with a contact hole connected to a gate, and a conductive film 115. An insulation layer such as silicon oxide or silicon nitride and the like may be formed between the first support substrate 10 and the thin film transistor 110. Water or gas and the like can be suppressed from entering the interior using this insulation layer.

An interlayer insulation layer 200 arranged with a contact hole 250 is formed so as to cover the thin film transistor 110 (FIG. 5). Next, a stacked conductive layer corresponding to the pixel electrode 300 and an inorganic insulation layer corresponding to the protective layer 350 are formed so as to cover the interlayer insulation layer 200 (FIG. 6). Following this, the stacked conductive layer and inorganic insulation layer are etched to form a pattern of the pixel electrode 300 and protective layer 350. This process is explained using the expanded region A (vicinity of the end part of the pixel electrode 300) shown in FIG. 6.

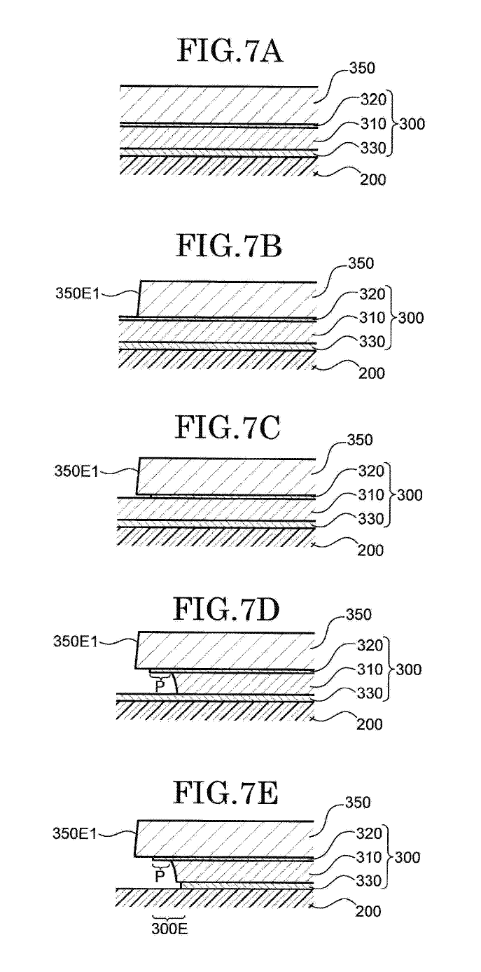

FIG. 7A˜FIG. 7E are diagrams showing an expanded view of an end part of a pixel electrode for explaining a process after FIG. 6 of a manufacturing method of the display device in the first embodiment of the present invention. FIG. 7A is an expanded view of the region A in FIG. 6. A third conductive layer 330, first conductive layer 310 and second conductive layer 320 are stacked in sequence above the interlayer insulation layer 200. In the present example, the first conductive layer 310 is an Ag film and has a film thickness of 130 nm (80 nm or more and 200 nm or less is preferred). The second conductive layer 320 is an ITO film and has a film thickness of 15 nm (5 nm or more and 25 nm or less is preferred). In particular, the second conductive layer 320 is often thinner than the first conductive layer 310 due to the properties demanded. The third conductive layer 330 is an ITO film and has a film thickness of 50 nm (20 nm or more and 70 nm or less is preferred). The protective layer 350 is a SiO2 film and has a film thickness of 300 nm (150 nm or more and 500 nm or less is preferred).

In this state, a resist is formed in the surface of the protective layer 350, the protective layer 350 is etched and the resist is stripped off. Dry etching is used for etching the protective layer 350 in the present example. The resist pattern corresponds to the pattern of the pixel electrode 300. The exterior side end part 350E1 of the protective layer 350 is formed by this etching process (FIG. 7B). At this point, the interior side end part 350E2 of the protective layer 350 is not formed. That is, the pixel electrode 300 (second conductive layer 320) is not exposed.

Next, the protective layer 350 is used as a mask and the second conductive layer 320 is etched (FIG. 7C). In the present example, the second conductive layer 320 is etched using wet etching using an ITO etchant. For example, a mixed acid comprised from phosphoric acid, nitric acid and acetic acid is used for the ITO etchant. Oxalic acid may also be used for the ITO etchant. Furthermore, the protective layer 350 and the second conductive layer 320 are used as a mask and the first conductive layer 310 is etched (FIG. 7D). In the present example, the first conductive layer 310 is etched using wet etching using an Ag etchant. For example, a mixed acid comprised from phosphoric acid, nitric acid and acetic acid is used for the Ag etchant. This etching process requires a longer time the thicker the film thickness of the first conductive layer 310. In addition, it is necessary to sufficiently secure an over-etching time period in order to sufficiently perform this etching process. As a result, etching also proceeds in a horizontal direction of the first conductive layer 310 and the end part of the second conductive layer 320 is formed into an eave shaped protrusion part P.

Furthermore, the protective layer 350, second conductive layer 320 and first conductive layer 310 are used as a mask and the third conductive layer 330 is etched (FIG. 7E). The third conductive layer 330 is etched using wet etching the same as when etching the second conductive layer 320. At this time, although it may be considered that the protrusion part P of the second conductive layer 320 is also etched by being exposed to the etchant, actually it is confirmed by experiment that the protrusion part P remains. Since the protrusion part P which remains is very thin (15 nm), it may be easily damaged by an external force. On the other hand, in the present example, damage is suppressed by the protective layer 350 supporting the protrusion part P. Furthermore, the end part of the third conductive layer 330 is located further to the interior than the end part of the first conductive layer 310 when etching the third conductive layer 330.

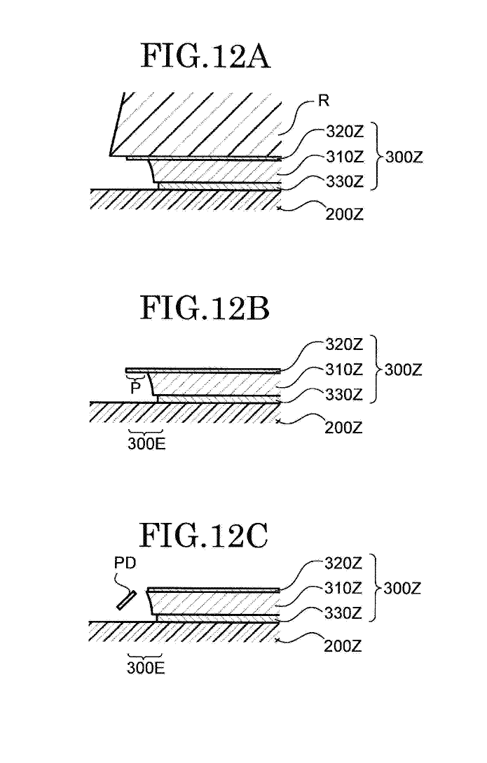

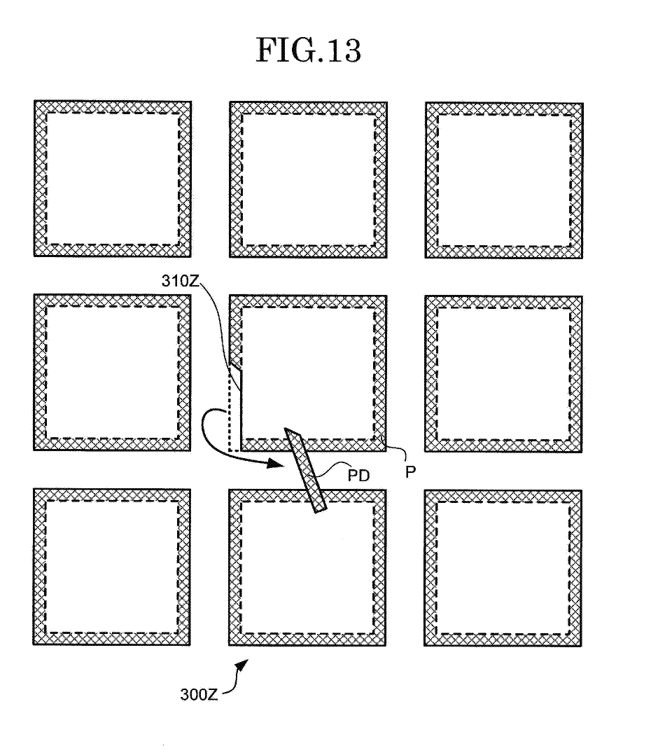

Here, the type of problems that occur in the case where the protective layer 350 is not used as in a conventional example is simply explained using FIG. 12A˜FIG. 12C and FIG. 13.

FIG. 12A˜FIG. 12C are diagrams for explaining an example of the problems that occur in a manufacturing method of a conventional display device. In the case of a conventional display device in which the protective layer 350 described above is not present, a resist R as shown in FIG. 12A is used in order to form a pattern of a pixel electrode 300Z. In addition, when the second conductive layer 320, first conductive layer 310 and third conductive layer 330 are etched in sequence the same as described above using the resist R as a mask, the protrusion part P is present in a state without support from the protective layer 350 (FIG. 12B). As a result, the possibility that a part of the protrusion part P is damaged by the application of an external force causing the damaged part PD to occur increases (FIG. 12C).

FIG. 13 is a diagram for explaining an example of the problems that occur in a manufacturing method of a conventional display device. FIG. 13 corresponds to FIG. 3 described above. The hatched part in FIG. 13 corresponds to the protrusion part P. As a result, the interior side of the dotted line corresponds to the location where the first conductive layer 310 is present. When a part of the protrusion part P is damaged and the damaged part PD occurs, the damaged part PD may become attached to the surface of the pixel electrode 300Z (second conductive layer 320Z). Although defects may occur in a display just simply by the damaged part PD becoming attached to the surface of the pixel electrode 300Z, when the damaged part PD becomes attached so as to bridge adjacent pixels as is shown in FIG. 13, the adjacent pixel electrode short circuits. As a result, the adjacent pixels appear as defects in a display. In this way, preventing damage to the protrusion part P contributes significantly to reducing defects in a display. According to the present embodiment, since it is possible to prevent damage to the protrusion part P by the presence of the protective layer 350, it is possible to reduce defects in a display caused by short circuits between adjacent pixel electrodes.

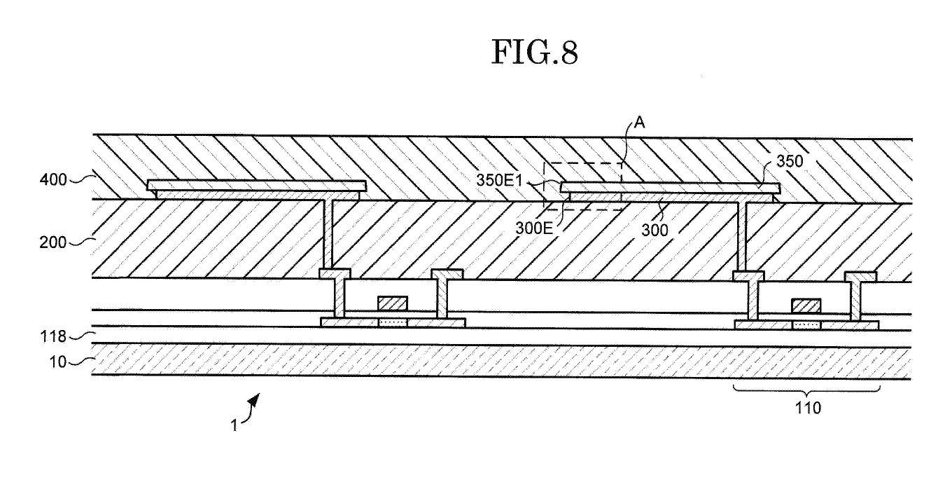

FIG. 8 is a diagram for explaining a process after FIG. 7A-7E of a manufacturing method of the display device in the first embodiment of the present invention. FIG. 8 shows a state where a material (photosensitive acrylic resin) which serves as the bank layer 400 is coated in the state shown in FIG. 7E. Following this, a pattern of the bank layer 400 is formed and subsequently a pattern of the protective layer 350 is formed. This process is explained using the expanded region A shown in FIG. 8.

FIG. 9A˜9D are diagrams showing an expanded view of an end part of a pixel electrode for explaining a process after FIG. 8 of a manufacturing method of the display device in the first embodiment of the present invention. FIG. 9A corresponds to FIG. 8. The bank layer 400 with a desired pattern is formed by performing an exposure, development and sintering process of the coated photosensitive acrylic resin. The bank layer 400 is formed so as to expose a part of the surface of the protective layer 350 (FIG. 9B).

Next, using the bank layer 400 as a mask, the protective layer 350 in the region which is exposed is etched, the surface of the pixel electrode 300 (second conductive layer 320) is exposed, and the interior side end part 350E2 is formed (FIG. 9C). This etching is performed using dry etching. Oxygen is added to the etching gas and etching of the protective layer 350 proceeds while removing the surface of the bank layer 400. As a result, in the present example, the surface of the bank layer 400 and the side wall of the interior side end part 350E2 of the protective layer 350 are almost consecutively linked.

In addition, since the protective layer 350 is etched while removing the surface of the bank layer 400, the side wall of the interior side end part 350E2 is provided with a gentle inclination. As a result, in the present example, the side wall of the interior side end part 350E2 of the protective layer 350 includes a more gentle inclination than the side wall of the exterior side end part 350E1. Furthermore, the relationship between the inclination of the side wall of the interior side end part 350E2 and the inclination of the exterior side end part 350E1 is not limited to this example. In addition, the length Lc from the interior side end part 350E2 to the exterior side end part 350E1 is desired to be longer than the film thickness Lt of the protective layer 350. In addition, since it is possible to obtain the effect of preventing damage to the protrusion part P in the case where the length of a part which overlaps the first conductive layer 310 of the protective layer 350 is zero, it is preferred that the protective layer 350 extends at least so as to overlap as far as above the first conductive layer 310. Furthermore, the length of a part which overlaps above the first conductive layer 310 is preferred to be a quarter or more of the length Lc.

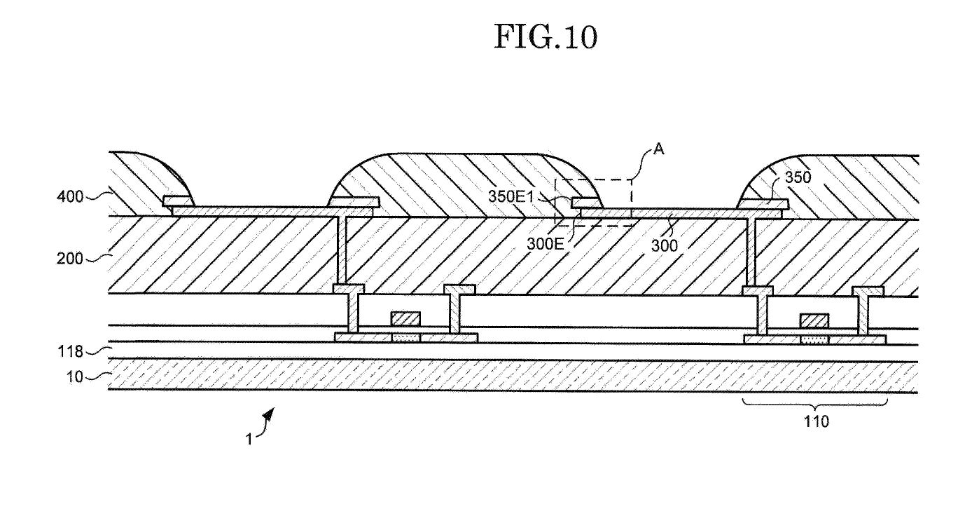

FIG. 10 is a diagram for explaining the entire structure in FIG. 9C. The bank layer 400 exposes the interior side end part 350E2 of the protective layer 350 and a part of the surface of the pixel electrode 300 (second conductive layer 320). On the other hand, the bank layer 400 covers the region except this exposed part, that is, the space between adjacent pixel electrodes 300 (including the exterior side end part 350E1 of the protective layer 350 and the end part of the pixel electrode 300). Following this, the structure of the first substrate 1 shown in FIG. 2 is realized when the light emitting layer 500, translucent electrode 600 and sealing layer 700 are formed to cover the bank layer 400 (FIG. 9D). Since it is possible to suppress damage to the protrusion part P using the first substrate 1 in the present embodiment, it is possible to reduce defects caused by short circuits between pixel electrodes 300.

### Second Embodiment

Although the bank layer 400 was arranged exposing the interior side end part 350E2 of the protective layer 350 in the first embodiment, an example is explained in the second embodiment where a bank layer 400A is arranged covering the interior side end part 350E2. A manufacturing method of a display device arranged with the bank layer 400A is explained.

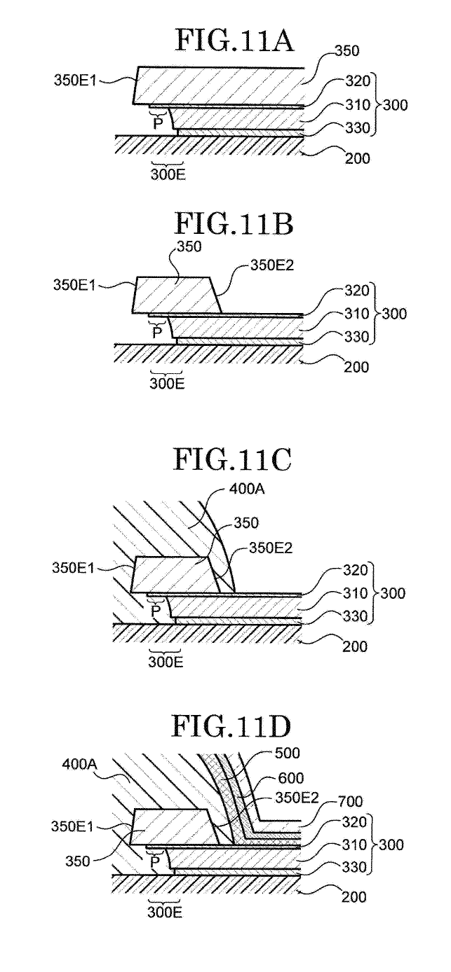

FIG. 11A˜11D are diagrams for explaining the processes corresponding to FIG. 9A˜9D in a manufacturing method of a display device in a second embodiment of the present invention. FIG. 11A is the same as FIG. 7E. The manufacturing process following this is different from the manufacturing process in the first embodiment. In the present example, a part of the surface of the pixel electrode 300 (second conductive layer 320) is exposed by etching the protective layer 350 before forming the bank layer 400. This etching process is performed by wet etching or dry etching using a mask formed by a resist. As a result, in the second embodiment the interior side end part 350E2 of the protective layer 350 is formed in advance before the bank layer 400A is formed (FIG. 11B).

Next, a part of the surface of the pixel electrode 300 (second conductive layer 320) is exposed and the bank layer 400A is formed to further cover the interior side end part 350E2 of the protective layer 350 compared to the first embodiment (FIG. 11C). The structure of the first substrate in the second embodiment is realized when the light emitting layer 500, translucent electrode 600 and sealing layer 700 are formed to cover the bank layer 400A (FIG. 11D).

### Other Embodiments

The protective layer 350 may also be formed using an inorganic conductive material (titanium: Ti, tantalum: Ta etc.). In this case, etching of the protective layer 350 may be performed using a chlorine based etching gas in the case of Ti or fluorine based etching gas in the case of Ta.

In the category of the concept of the present invention, a person ordinarily skilled in the art could conceive of various modifications and correction examples and could understand that these modifications and correction examples belong to the scope of the present invention. For example, with respect to each embodiment described above, a person ordinarily skilled in the art could appropriately perform an addition or removal of structural components or design modification or an addition of processes or an omission or change in conditions which are included in the scope of the present invention as long as they do not depart from the subject matter of the present invention.

What is claimed is:

1. A display device comprising:
a display region arranged with a plurality of pixels in a matrix shape;
a pixel electrode arranged corresponding to the pixel, and including at least a first conductive layer and a second conductive layer arranged above the first conductive layer, an end part of the second conductive layer existing further to the exterior than an end part of the first conductive layer;
a protective layer arranged above the second conductive layer, and covering a region spreading further to the exterior than an end part of the first conductive layer of the second conductive layer so as to expose a part of a surface of the second conductive layer of a region stacked with the first conductive layer and the second conductive layer; and
a bank layer being an insulation material, and covering an end part of the pixel electrode and an end part of the protective layer so as to expose a part of the second conductive layer.

2. The display device according to claim 1, further comprising:
a light emitting layer contacting at least a part of the bank layer and a region exposed by the protective layer and the bank layer of the second protective layer; and
an opposing electrode arranged so as to cover the light emitting layer.

3. The display device according to claim 2, wherein a side wall on a side exposing the second conductive layer of the protective layer contacts the light emitting layer.

4. The display device according to claim 3, wherein a surface of the side wall and a surface of the bank layer are consecutively linked.

5. The display device according to claim 1, wherein a side wall on a side exposing the second conductive layer of the protective layer is covered by the bank layer.

6. The display device according to claim 1, wherein the protective layer is an inorganic insulation material.

7. The display device according to claim 1, wherein the protective layer is a conductive material

8. The display device according to claim 1, wherein the protective layer is thicker than the second conductive layer.

9. The display device according to claim 1, wherein the second conductive layer is thinner than the first conductive layer.

10. The display device according to claim 1, further comprising:
a third conductive layer arranged on an opposite side to the first conductive layer and the second conductive layer.

11. The display device according to claim 10, wherein the third conductive layer includes the same material as the second conductive layer, and an end part of the third conductive layer is located further to the inner side than an end part of the first conductive layer.

12. The display device according to claim 1, wherein the first conductive layer is a metal layer having light reflective properties, and the second conductive layer is a metal oxide conductive layer having transparent properties.

13. The display device according to claim 1, wherein an incline of a side wall on a side exposing the second conductive layer of the protection layer is gentler than an incline of a side wall of the protection layer at an end part side of the second conductive layer.
